(19) United States
(12) Patent Application Publication
(10) Pub. No.: US 2026/0031821 A1
(43) Pub. Date: Jan. 29, 2026

(54) DELAY LOCKED LOOP WITH 2-STEP MEASURE INITIALIZATION PROCESS USING COMPLEMENTARY AND QUADRATURE CLOCK SIGNALS

(71) Applicant: Micron Technology, Inc., Boise, ID (US)

(72) Inventors: Hyunui Lee, Kanagawa (JP); Yasuo Satoh, Ibaraki (JP)

(21) Appl. No.: 19/186,972

(22) Filed: Apr. 23, 2025

Related U.S. Application Data
(60) Provisional application No. 63/676,072, filed on Jul. 26, 2024.

(51) Int. Cl. H03L 7/081; G11C 7/22

(52) U.S. Cl. CPC H03L 7/0816; G11C 7/222

(57) ABSTRACT

This disclosure is generally directed to a delay locked loop (DLL) to generate an output clock signal with a desired phase value. The DLL may include circuitry to delay an input clock signal with a number of delay cells to generate the output clock signal with the desired phase value. The DLL may provide the output clock signal aligned (e.g., nearly aligned) with data signals of a circuit, such as a memory device, to compensate for various delays of the circuit. The DLL may generate the output clock signal by performing a single-step measure initialization process or a 2-step measure initialization process to determine the number of the delay cells. The DLL may generate complementary clock signals and, in some case, quadrature clock signals, based on an input clock signal to perform the 2-step measure initialization process.

### CROSS-REFERENCE TO RELATED APPLICATIONS

This application claims priority to U.S. Provisional Application No. 63/676,072, filed Jul. 26, 2024, which is incorporated by reference herein in its entirety.

### BACKGROUND

The present disclosure generally relates to memory devices. A memory device may receive a clock signal to perform memory operations. The memory operations may include writing input data in memory cells of the memory device and reading data stored in the memory cells. Some circuits and components of the memory device may perform one or more operations with various delays and/or induce various delays to the clock signal. Such delays may cause distortion in a phase of the clock signal. As such, in some cases, if not compensated for, a phase of the clock signal may not be aligned with a phase of data being written to and/or data being read from the memory cells. Systems and methods for clock signal phase alignment with the phase of data being written to or read from the memory cells is desired.

This section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### BRIEF DESCRIPTION OF THE DRAWINGS

Various aspects of this disclosure may be better understood upon reading the following detailed description and upon reference to the drawings described below in which like numerals refer to like parts.

FIG. 1 is a block diagram of an electronic device, according to embodiments of the present disclosure;

FIG. 2 is a block diagram illustrating a delay locked loop (DLL) of the memory device of FIG. 1 that may perform a 2-step measure initialization process to generate an output clock signal using measure initialization complementary clock signals or measure initialization quadrature clock signals, according to embodiments of the present disclosure;

FIG. 3 is a process for operating the DLL of FIGS. 1 and 2, according to embodiments of the present disclosure;

FIG. 4 is a timing diagram for performing a first step of the 2-step measure initialization process by the DLL of FIGS. 1 and 2 based on the process of FIG. 3 using the measure initialization complementary clock signals when input clock signal of the DLL has a first frequency, according to embodiments of the present disclosure;

FIG. 5 is a timing diagram for performing normal operations of the DLL of FIGS. 1 and 2 based on a coarse clock adjustment at a first step of the 2-step measure initialization process shown in FIG. 4, according to embodiments of the present disclosure;

FIG. 6 is the timing diagram for performing the first step of the 2-step measure initialization process of the DLL of FIGS. 1 and 2 based on the process of FIG. 3 using the measure initialization complementary clock signals when the input clock signal has a second frequency lower than the first frequency, according to embodiments of the present disclosure; and

FIG. 7 is a timing diagram 240 for performing a second step of the 2-step measure initialization process of the DLL of FIGS. 1 and 2 based on the process of FIG. 3 using measure initialization quadrature clock signals when the input clock signal has the second frequency, according to embodiments of the present disclosure; and

FIG. 8 is a timing diagram for performing normal operations of the DLL of FIGS. 1 and 2 based on a coarse clock adjustment at the second step of the 2-step measure initialization process shown in FIG. 7, according to embodiments of the present disclosure.

### DETAILED DESCRIPTION

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. Furthermore, the particular features, structures, or characteristics may be combined in any suitable manner in one or more embodiments. Use of the terms “approximately,” “near,” “about,” “close to,” and/or “substantially” should be understood to mean including close to a target (e.g., design, value, amount), such as within a margin of any suitable or contemplatable error (e.g., within 0.1% of a target, within 1% of a target, within 5% of a target, within 10% of a target, within 25% of a target, and so on). Moreover, it should be understood that any exact values, numbers, measurements, and so on, provided herein, are contemplated to include approximations (e.g., within a margin of suitable or contemplatable error) of the exact values, numbers, measurements, and so on. Additionally, the term “set” may include one or more. That is, a set may include a unitary set of one member, but the set may also include a set of multiple members.

This disclosure is generally directed to a delay locked loop (DLL) to generate an output clock signal with a desired phase value. The DLL may include circuitry to delay an input clock signal by a delay value to generate the output clock signal with the desired phase value. The DLL may provide the output clock signal aligned (e.g., nearly aligned) with data signals of a circuit, such as a memory device, to compensate for various delays of the circuit. The DLL may generate the output clock signal by performing a single-step measure initialization process or a 2-step measure initialization process, as will be appreciated.

The DLL may perform a first step of the measure initialization process based on receiving the input clock signal. The DLL may perform the first step by generating the measure initialization complementary clock signals having phase values that are 360 degrees out of phase based on receiving the input clock signal and determining a first coarse clock adjustment for delaying the input clock signal based on the desired phase value. The DLL may generate the output clock signal by delaying the measure initialization complementary clock signals based on the first coarse clock adjustment.

The DLL may include delay cells for providing the first coarse clock adjustment. Each delay cell may delay an input signal with a respective delay when selected. For example, an input signal may pass-through the selected cells with the respective delay. Moreover, the non-selected delay cells may be bypassed. The DLL may determine a first number of delay cells for providing the first coarse clock adjustment. The DLL may compare the first number of delay cells to a predetermined threshold number of delay cells. The DLL may generate the output clock signal based on combining the delayed measure initialization complementary clock signals delayed by the first number of delay cells in response to the first number of delay cells being lower than the threshold. As such, the DLL may generate the output clock signal using the single-step measure initialization process. In some cases, the input clock signal may have a frequency equal to or higher than a frequency threshold when the first number of delay cells is lower than the threshold.

Alternatively, the DLL may perform a second step associated with the 2-step measure initialization process based on the first number of delay cells being equal to or higher than the threshold. The DLL may perform the second step by generating the measure initialization quadrature clock signals having phase values that are 180 degrees out of phase based on receiving the input clock signal and determining a second coarse clock adjustment for delaying the input clock signal based on the desired phase value. The DLL may generate the output clock signal by delaying the measure initialization quadrature clock signals based on the second coarse clock adjustment.

The DLL may determine a second number of delay cells for providing the second coarse clock adjustment. In some cases, the second coarse clock adjustment may have a lower delay value compared to a delay value (e.g., a duration) of the first coarse clock adjustment described above with respect to the first step. As such, the DLL may generate the output clock signal based on selecting a second number of delay cells that are less than the first number of delay cells. The DLL may generate the output clock signal by combining the measure initialization quadrature clock signals delayed by the second number of delay cells. As such, the DLL may generate the output clock signal using the second step of the 2-step measure initialization process.

With the foregoing in mind, consecutive rising edges of the measure initialization quadrature clock signals may have reduced time gaps (e.g., margins) compared to consecutive rising edges of the measure initialization complementary clock signals. Moreover, a frequency of the measure initialization quadrature clock signals and the measure initialization complementary clock signals may be based on a frequency of the input clock signal. As such, in some cases, the DLL may have an increased bandwidth based on using the single-step measure initialization process and the 2-step measure initialization process by accommodating for differences in time gaps (or margins) between consecutive rising edges of input signals with wider span of frequencies.

The increased time gaps between the consecutive measure initialization complementary clock signals compared to the measure initialization quadrature clock signals may improve edge detection capability of the DLL at higher operating frequencies. For example, in some cases, the DLL may use the measure initialization complementary clock signals for the coarse clock adjustment when the input clock signal has a frequency equal to or higher than the frequency threshold. In such cases, the DLL may generate the output clock signal using the single-step measure initialization process.

Moreover, selecting a number of delay cells lower than the predetermined threshold number of delay cells may improve the signal quality of the output clock signal. As such, in some cases, the DLL may use the measure initialization quadrature clock signals for the coarse clock adjustment when the first step of the measure initialization process determines a number of delay cells equal to or higher than the predetermined threshold number of delay cells. In such cases, the DLL may generate the output clock signal using the 2-step measure initialization process. In specific cases, the input clock signal has a frequency lower than the frequency threshold when the DLL generates the output clock signal using the 2-step measure initialization process.

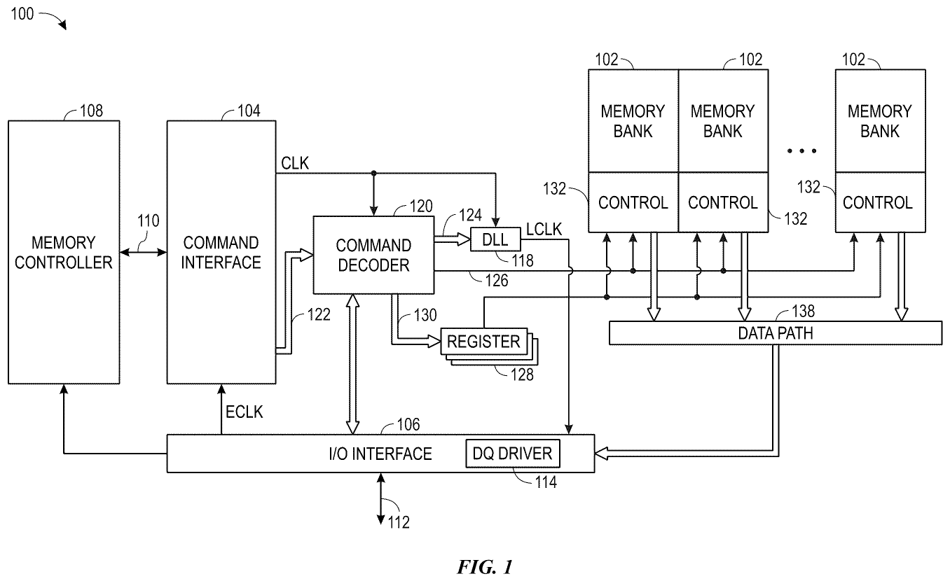

FIG. 1 depicts a block diagram illustrating certain features of a memory device 100 (e.g., a memory subsystem of an apparatus), according to embodiments of the present disclosure. Specifically, the block diagram of FIG. 1 depicts a functional block diagram illustrating certain functionality of the memory device 100. The memory device 100 may include a random access memory (RAM) device, a ferroelectric RAM (FeRAM) device, a dynamic RAM (DRAM) device, a static RAM (SRAM) device (including a double data rate SRAM device), flash memory, and/or a 3D memory array including phase change (PC) memory and/or other chalcogenide-based memory, such as self-selecting memories (SSM).

The memory device 100 may include a number of memory banks 102 each inclusive of one or more memory arrays. Various configurations, organizations, and sizes of the memory banks 102 on the memory device 100 may be used based on an application and/or design of the memory device 100 within an electrical system. For example, in different embodiments, the memory banks 102 may include a different number of rows and/or columns of memory cells. Each memory cell of such memory devices may include a corresponding logic storing device (e.g., a capacitor, a resistor, or the resistance of the chalcogenide material(s)).

The memory device 100 may also include a command interface 104 and an input/output (I/O) interface 106. The command interface 104 is configured to provide a number of signals received from a processor (e.g., a processor subsystem of an apparatus) or a controller, such as a memory controller 108. For example, an electronic device may include the processor coupled to the memory device 100. In different embodiments, the memory controller 108 may include one or more processors (e.g., memory processors), one or more programmable logic fabrics, or any other suitable processing components.

In some embodiments, a bus 110 may provide a signal path or a group of signal paths to allow bidirectional communication between the memory controller 108, the command interface 104 and the I/O interface 106. For example, the memory controller 108 may receive memory access requests from the I/O interface 106 via the command interface 104 and the bus 110. The memory access requests may be indicative of a request for accessing one or more target memory cells. The memory controller 108 may provide commands and/or instructions for performing memory operations to the command interface 104 via the bus 110. The memory operations may include writing input data in memory cells of the memory device, reading data stored in the memory cells, and/or error correcting code (ECC) operations, among other possibilities.

Similarly, an external bus 112 (e.g., a system bus) may provide another signal path or group of signal paths to allow for bidirectional transmission of signals, such as data signals (e.g., DQ signals, read data, write data) and access commands (e.g., the memory access requests, read/write requests), between the I/O interface 106, the memory controller 108, a command decoder 120, and/or other components. Thus, the memory controller 108 may provide various signals (e.g., the access commands, the access instructions, or other signals) to different components of the memory device 100 to facilitate the transmission and receipt of data to be written to or read from the memory banks 102.

In some embodiments, the command interface 104 may receive an external clock signal (ECLK) from the I/O interface 106 via the external bus 112. For example, an external device may provide the ECLK to the memory device 100. The command interface 104 may provide (e.g., generate) an internal clock signal (CLK) based on the ECLK. The command interface 104 may provide the CLK to the memory controller 108, the command decoder 120, and/or an internal clock generator, such as a DLL 118 circuit, among other things. Alternatively or additionally, the memory controller 108, the command decoder 120, and/or the internal clock generator or the DLL 118 may directly receive the CLK (or the ECLK) from the I/O interface 106, among other possibilities.

The DLL 118 may generate a phase controlled local clock signal (LCLK) based on receiving the CLK (or the ECLK). Moreover, in some cases, the DLL 118 may generate a latching signal and one or more delayed latching signals based on receiving the CLK. In such cases, the DLL 118 may provide the latching signal and the delayed latching signal to the memory banks 102 to facilitate accessing a number of memory cells of one or more of the memory arrays.

The DLL 118 may adjust (e.g., delay) a phase of the received clock signal CLK (or ECLK) to generate the LCLK for performing the memory operations. In some cases, various components of the memory device 100 such as the memory controller 108, the command decoder 120, the registers 128, control blocks 132, memory banks 102, data path 138, routing traces therebetween, among other things, may provide a phase delay to the data signals. The DLL 118 may compensate for at least a portion of a cumulative phase delay of write data and/or read data caused by various components of the memory device 100.

The DLL 118 may generate the LCLK with a desired phase value by delaying the CLK based on the cumulative phase delay of the write data and/or the read data. For example, the DLL 118 may generate the LCLK with the desired phase value based on a phase value of write data at the control blocks 132 and/or a phase value of read data at the I/O interface 106. In some cases, the DLL 118 may output the LCLK having a rising (e.g., or falling) edge closer to that of the write data or the read data compared to a rising (e.g., or falling) edge of the CLK. In specific cases, the DLL 118 may output the LCLK with a matched (e.g., nearly matched, nearly aligned) phase value compared to that of the write data or the read data.

The DLL 118 may output the LCLK to the I/O interface 106 and/or the command decoder 120, among other possibilities. The I/O interface 106 may include a data driver 114 (e.g., DQ driver) to drive the data signals based on a reference clock signal. The data driver 114 may use the LCLK as the reference signal for outputting (e.g., clocking-out) the read data via the external bus 112. The data driver 114 may compensate for at least a portion of the cumulative phase delay of the write data caused by various components of the memory device 100 based on using the LCLK as the reference clock signal to output the read data. As such, the I/O interface 106 may output the write data with improved signal quality and/or reduced jitter or skew based on an improved phase alignment between the reference clock signal (e.g., the LCLK) and the read data.

The command decoder 120 may receive the CLK and/or the LCLK. In some cases, the command decoder 120 may also receive the access commands via a bus 122 and/or through the I/O interface 106 received via the external bus 112. For example, the command decoder 120 may receive the access commands provided by the memory controller 108 via the bus 110 and/or through the I/O interface 106 transmitted by one or more external processors. The command decoder 120 may receive the access commands provided using a memory command protocol such as a multi-clock cycle memory command protocol. For example, the memory command protocol may be based at least in part on the number of pins of the memory device 100 or the I/O interface 106, the number of memory cell rows and/or columns of the memory banks 102, and the number of memory banks 102.

The command decoder 120 may decode the access commands and/or the memory access requests to generate corresponding access instructions for accessing the target memory cells. The command decoder 120 may decode the access commands and/or the memory access requests using one or multiple clock cycles of the CLK or the LCLK. The command decoder 120 may provide the access instructions to the control blocks 132 of the memory banks 102 via a bus path 126. The command decoder 120 may transmit the access instructions using one or multiple clock cycles of the CLK or the LCLK.

The command decoder 120 may also transmit various signals to one or more registers 128 via one or more global wiring lines 130. For example, one of the one or more registers 128 may provide instructions to configure various modes of programmable operations and/or configurations of the memory device 100. Moreover, the memory device 100 may include other decoders, such as row decoders and column decoders, to facilitate access to the memory banks 102, as discussed below.

In some embodiments, each memory bank 102 may include a respective control block 132. In some cases, each of the control blocks 132 may also provide row decoding and column decoding capability based on receiving the access instructions. Accordingly, the control block 132 may facilitate accessing the memory arrays of the respective memory banks 102. For example, the control block 132 may include circuitry (e.g., logic circuitry) to facilitate accessing the memory cells of the respective memory banks 102 based on receiving the access instructions.

In some cases, the control blocks 132 may receive the access instructions and determine target memory banks 102 associated with the target memory cells. Moreover, the control blocks 132 may also provide timing control and data control functions to facilitate execution of different commands with respect to the respective memory banks 102. In specific embodiments, the command decoder 120 may include the control blocks 132.

It should be appreciated that in different embodiments, the memory device 100 may include additional or alternative components. That is, the memory device 100 may include additional or alternative components such as power supply circuits (for receiving external VDD and VSS signals), read/write amplifiers (to amplify signals during read/write operations), temperature sensors (for sensing temperatures of the memory device 100), etc. Accordingly, it should be understood that the block diagram of FIG. 1 is only provided to highlight certain functional features of the memory device 100 to aid in the subsequent detailed description.

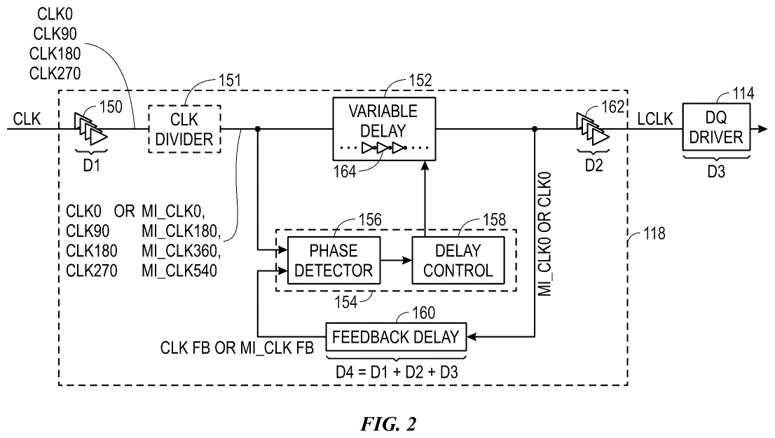

FIG. 2 is a block diagram illustrating the DLL 118 of the memory device 100 that may perform a 2-step measure initialization process to generate the LCLK using complementary or quadrature clock signals, according to embodiments of the present disclosure. In some embodiments, the DLL 118 may include a deserializer 150, a clock divider 151, a variable delay circuit 152, a measure initialization circuit 154 including a phase detector circuit 156 and a delay control circuit 158, a feedback delay circuit 160, and a serializer 162. It should be appreciated that in alternative or additional embodiments, the DLL 118 may include additional or different components.

In some cases, the DLL 118 may perform a first step and/or a second step of the measure initialization process to generate the LCLK (e.g., an output clock signal) based on receiving the CLK. In alternative or additional cases, the DLL 118 may generate the LCLK based on receiving initialization instructions. For example, the DLL 118 may receive the initialization instructions from the memory controller 108 or the external devices described above with respect to FIG. 1. In the depicted embodiment, the DLL 118 may output the LCLK to the data driver 114 of the memory device 100 described above. In alternative or additional embodiments, the DLL 118 may output the LCLK to any other viable component.

The deserializer 150 may generate complementary clock signals, CLK0 and CLK180, or CLK90 and CLK270, based on receiving the CLK. In some cases, the deserializer 150 may generate the complementary clock signals having a frequency that is half of a frequency of the CLK. The complementary clock signal may have phase values that are 180 degrees out of phase. The deserializer 150 may output the complementary clock signals to the clock divider 151.

The clock divider 151 may generate measure initialization complementary clock signals, MI_CLK0 and MI_CLK360, or MI_CLK180 and MI_CLK540, based on the complementary clock signals. In some embodiments, the clock divider 151 may generate the measure initialization complementary clock signals with a frequency that is half of a frequency of the complementary clock signals. The clock divider 151 may output the measure initialization complementary clock signals to the variable delay circuit 152 and the phase detector circuit 156. The DLL 118 may perform a first step of the measure initialization process based on the measure initialization complementary clock signals.

In some cases, the deserializer 150 may generate quadrature clock signals, CLK0, CLK90, CLK180, and CLK270, based on receiving the CLK. In some cases, the deserializer 150 may generate the quadrature clock signals having a frequency that is half of a frequency of the CLK. The quadrature clock signals may have phase values that are 90 degrees out of phase. The deserializer 150 may output the quadrature clock signals to the clock divider 151.

In some embodiments, the clock divider 151 may generate the measure initialization complementary clock signals or the measure initialization quadrature clock signals having a frequency that is half of a frequency of the quadrature clock signals. In some cases, the measure initialization complementary clock signals or the measure initialization quadrature clock signals may have a frequency that is a quarter of the frequency of the CLK. The clock divider 151 may output the measure initialization quadrature clock signals to the variable delay circuit 152 and the phase detector circuit 156. The DLL 118 may perform a second step of the measure initialization process based on the quadrature clock signals. In some embodiments, the clock divider 151 may be bypassed during normal operations of the DLL 118 and after the measure initialization process. As such, the deserializer 150 may output the complementary clock signals or the quadrature clock signals to the variable delay circuit 152 and the phase detector circuit 156 during the normal operations of the DLL 118.

The deserializer 150 may generate the quadrature clock signals based on receiving first instructions indicative of performing the second step of the measure initialization process. In some cases, the measure initialization circuit 154 (e.g., the delay control circuit 158) may generate the first instructions based on performing the first step of the measure initialization process. As such, the DLL 118 may perform the second step of the measure initialization process using the quadrature clock signals after performing the first step using the complementary clock signals. In specific cases, the measure initialization circuit 154 (e.g., the delay control circuit 158) may not generate the first instructions and/or may generate second instructions indicative of generating the LCLK based on performing the first step of the measure initialization process. For example, the measure initialization circuit 154 (e.g., the delay control circuit 158) may not generate the first instructions and/or may generate second instructions to omit performing the second step of the measure initialization process.

The variable delay circuit 152 may include multiple selectable delay cells 164, such as buffers or inverters, among other possibilities, to provide a coarse delay adjustment for generating the LCLK. For example, each delay cell 164 may provide a unit delay value to an input signal when selected. The delay cells 164 of the variable delay circuit 152 may initially remain unselected to perform the first step and the second step of the measure initialization process. As such, the variable delay circuit 152 may initially output (e.g., pass-through) the received measure initialization complementary clock signals or the received measure initialization quadrature clock signals to the feedback delay circuit 160 without a delay when performing the measure initialization process. For example, a mask operation (e.g., a mask signal) may disable the deserializer 162 when performing the measure initialization process. As such, the DLL 118 may not generate the LCLK when performing the measure initialization process.

In some cases, the measure initialization circuit 154 may select a number of the delay cells 164 of the variable delay circuit 152 based on performing the first step or the second step of the measure initialization process. In some cases, the measure initialization circuit 154 may select the delay cells 164 of the variable delay circuit 152 to provide the coarse delay adjustment by only performing the first step of the measure initialization process. In other cases, the measure initialization circuit 154 may select the delay cells 164 of the variable delay circuit 152 to provide the coarse delay adjustment by performing the first step and subsequently performing the second step of the measure initialization process.

The variable delay circuit 152 may provide one or more of the received measure initialization complementary clock signals or measure initialization quadrature clock signals to the feedback delay circuit 160 during the measure initialization process. By way of example, in the depicted embodiment, the variable delay circuit 152 may provide the MI_CLK0 to the feedback delay circuit 160 during the measure initialization process. As mentioned above, the clock divider 151 may be bypassed during the normal operations of the DLL 118 and after the measure initialization process. For example, the memory controller 108 or any other viable circuitry may generate instructions to bypass the clock divider 151 after the measure initialization process. As such, the variable delay circuit 152 may provide the CLK0 to the feedback delay circuit 160 during the normal operations. It should be appreciated that in alternative or additional cases, the variable delay circuit 152 may provide either of the clock signals CLK0, CLK90, CLK180, or CLK270, and MI_CLK180, MI_CLK360, or MI_CLK540 to the feedback delay circuit 160.

The feedback delay circuit 160 may include circuitry to delay the received measure initialization complementary clock signals or the received measure initialization quadrature clock signals based on a cumulative delay value D4. In the depicted embodiment, the cumulative delay value D4 may correspond to a cumulative delay value of the deserializer 150 D1, the serializer 162 D2, and the data driver 114 D3 for outputting (e.g., passing-through) the respective input signals.

In alternative or additional embodiments, the cumulative delay value D4 may be determined (e.g., pre-determined) based on delays of additional or different components. For example, the DLL 118 may provide the LCLK to additional or alternative components of the memory device 100 discussed above. In such embodiments, the cumulative delay value D4 may additionally or alternatively correspond to at least a portion of the delay values associated with such additional or alternative components. For example, cumulative delay value D4 may be associated with generating the LCLK with the desired phase value by delaying the CLK based on the cumulative phase delay of the write data and/or the read data within the memory system 100 discussed above.

The feedback delay circuit 160 may generate a feedback clock signal (CLK FB) by delaying the received complementary clock signal or quadrature clock signal (e.g., CLK0, CLK90, CLK180, or CLK270) based on the cumulative delay value D4 during the normal operations of the DLL 118. The feedback delay circuit 160 may generate a feedback clock signal (CLK FB) by delaying the received measure initialization complementary clock signal or measure initialization quadrature clock signal (e.g., MI_CLK0, MI_CLK180, MI_CLK360, or MI_CLK540) based on the cumulative delay value D4 during the measure initialization process of the DLL 118. The feedback delay circuit 160 may output the feedback clock signal to the phase detector circuit 156.

As mentioned above, the phase detector circuit 156 may also receive the complementary clock signals or the quadrature clock signals or the measure initialization complementary clock signals or the measure initialization quadrature clock signals from the deserializer 150. The phase detector circuit 156 may compare the feedback clock signal with the complementary clock signals or the quadrature clock signals during the normal operations. The phase detector circuit 156 may compare the feedback clock signal with the measure initialization complementary clock signals or the measure initialization quadrature clock signals during the measure initialization process. For example, the phase detector circuit 156 may include edge detection circuitry to determine the phase values of the received signals to compare the feedback clock signal with the complementary clock signals or the quadrature clock signals.

The phase detector circuit 156 may generate a phase error signal based on the comparison. The phase error signal may be indicative of a phase difference (e.g., a phase delay) between the feedback clock signal and the measure initialization complementary clock signals when performing the first step of the measure initialization process. The phase error signal may be indicative of a phase difference (e.g., a phase delay) between the feedback clock signal and the measure initialization quadrature clock signals when performing the second step of the measure initialization process.

The delay control circuit 158 may receive the phase error signal. The delay control circuit 158 may determine a number of the delay cells 164 of the variable delay circuit 152 for providing the coarse delay adjustment during the normal operation of the DLL 118. The delay control circuit 158 may compare the determined number of the delay cells 164 with a predetermined threshold number of delay cells 164 (e.g., 2, 3, 6, 9, 23, and so on) when performing the first step of the measure initialization process. The delay control circuit 158 may provide control signals to the variable delay circuit 152 to select the number of the delay cells 164 based on the number of the delay cells 164 being below the threshold. Moreover, the delay control circuit 158 may provide control signals to cause removing the mask signal.

For example, the delay control circuit 158 may remove the mask signal or provide the control signals to the memory controller 108 discussed above to initiate the normal operations of the DLL 118 by removing the mask signal and/or bypassing the clock divider 151. As such, the variable delay circuit 152 may receive the complementary clock signals. The variable delay circuit 152 may provide the coarse delay adjustment by delaying the complementary clock signals using the selected delay cells 164 during the normal operation of the DLL 118. Moreover, the deserializer 162 may generate the LCLK by combining the complementary clock signals, as delayed by the selected delay cells 164 of the variable delay circuit 152, in response to the mask signal being removed during the normal operation of the DLL 118.

Accordingly, the DLL 118 may only perform the first step of the measure initialization process when the number of the delay cells 164 are below the threshold during the first step. The variable delay circuit 152 may provide the coarse delay adjustment by delaying the complementary clock signals using the selected delay cells 164 during the normal operation of the DLL 118. Moreover, the deserializer 162 may generate the LCLK by combining the complementary clock signals, as delayed, during the normal operation of the DLL 118.

Alternatively, the delay control circuit 158 may provide control signals to the deserializer 150 indicative of outputting the measure initialization quadrature clock signals for performing the second step of the measure initialization process based on the number of the delay cells 164 being equal to or higher than the threshold. For example, the delay control circuit 158 may provide a flag signal based on the number of the delay cells 164 being equal to or higher than the threshold. As such, the DLL 118 may perform the second step of the measure initialization process using the measure initialization quadrature clock signals.

In particular, the phase detector circuit 156 may compare the feedback clock signal with the measure initialization quadrature clock signals to generate the phase error signal during the second step of the measure initialization process. The delay control circuit 158 may initiate the normal operations of the DLL 118 by determining a number of the delay cells 164 of the variable delay circuit 152 for providing the coarse delay adjustment during the normal operation of the DLL 118 based on the phase error signal. Accordingly, the variable delay circuit 152 may provide the coarse delay adjustment by delaying the quadrature clock signals using the selected delay cells 164 during the normal operation of the DLL 118. Moreover, the deserializer 162 may generate the LCLK by combining the quadrature clock signals, as delayed, during the normal operation of the DLL 118.

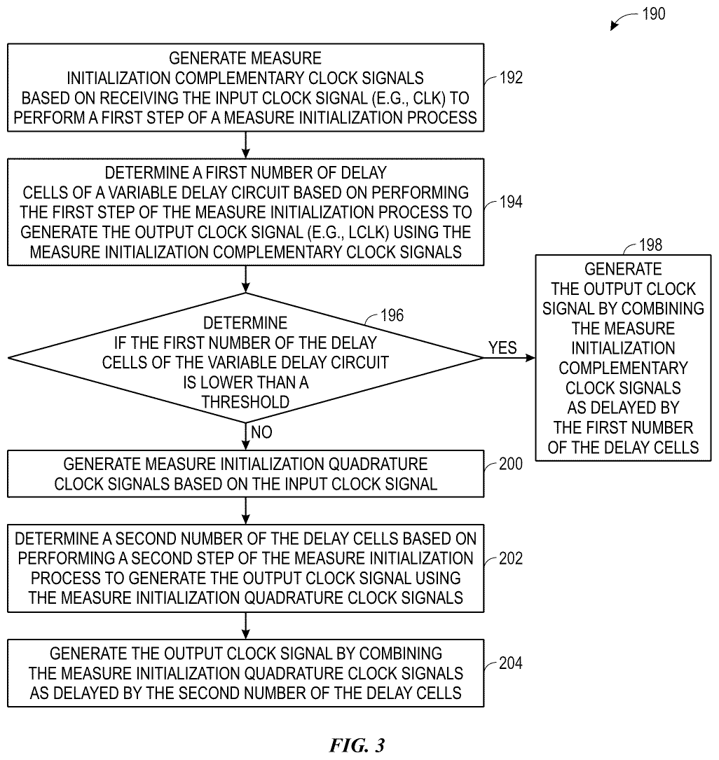

FIGS. 3-8 are directed to a process 190 and timing diagrams 220, 226, 230, 240, and 250 associated with the DLL 118 of FIG. 2 and/or the memory device 100 of FIG. 1. It should be appreciated that the process 190 and the timing diagrams 220, 226, 230, 240, and 250 are provided by the way of example and the DLL 118 of FIG. 2 and/or the memory device 100 of FIG. 1 may perform alternative or additional processes based on alternative or additional timing diagrams. Moreover, the timing diagrams 220, 226, 230, 240, and 250 are only provided for illustration purposes. That is, although the process 190 is described with respect to the timing diagrams 220, 226, 230, 240, and 250, it should be appreciated that the DLL 118 may perform the operations of the process 190 based on different timing diagrams.

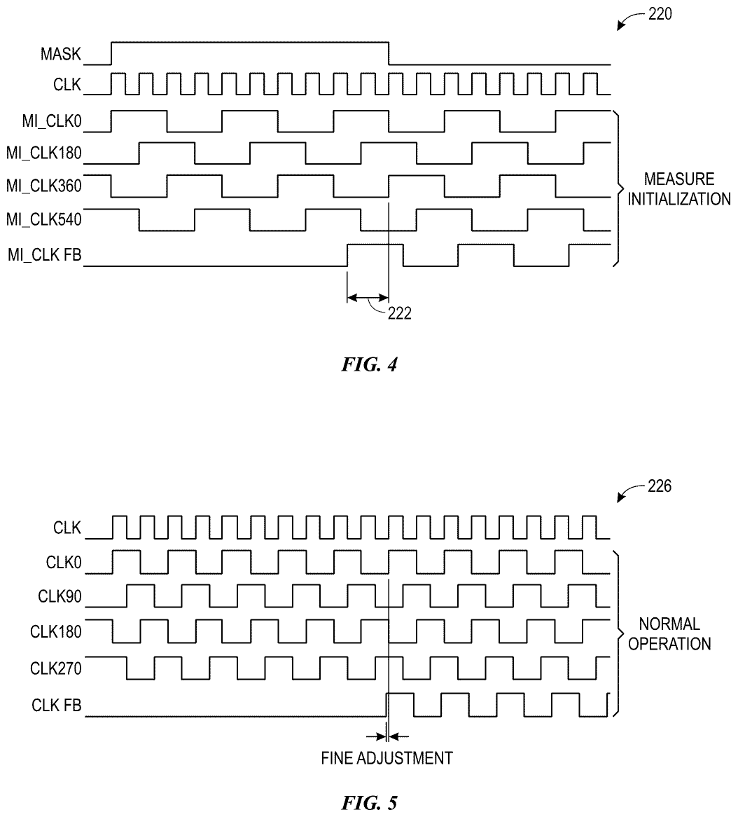

FIG. 3 is the process 190 for operating the DLL 118 of FIGS. 1 and 2, according to embodiments of the present disclosure. FIG. 4 is the timing diagram 220 for performing the measure initialization process of the DLL 118 of FIGS. 1 and 2 by the measure initialization complementary clock signals when the CLK has a first frequency, according to embodiments of the present disclosure. FIG. 5 is the timing diagram 226 for performing the normal operations of the DLL 118 of FIGS. 1 and 2 based on a coarse clock adjustment by a first step of the measure initialization process (e.g., the 2-step measure initialization process) of the timing diagram 220, according to embodiments of the present disclosure.

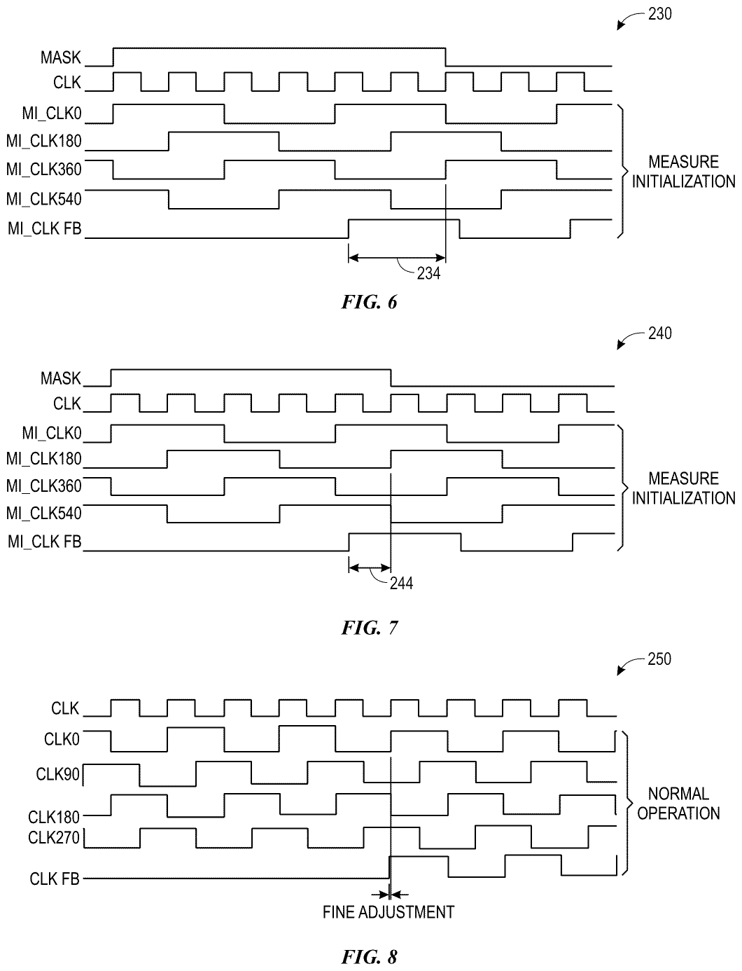

FIG. 6 is the timing diagram 230 for performing the measure initialization process of the DLL 118 of FIGS. 1 and 2 by the measure initialization complementary clock signals when the CLK has a second frequency lower than the first frequency, according to embodiments of the present disclosure. Moreover, FIG. 7 is the timing diagram 240 for performing the measure initialization process of the DLL 118 of FIGS. 1 and 2 by the measure initialization quadrature clock signals when the CLK has the second frequency, according to embodiments of the present disclosure. Furthermore, FIG. 8 is the timing diagram 226 for performing the normal operations of the DLL 118 of FIGS. 1 and 2 based on a coarse clock adjustment by a second step of the measure initialization process of the timing diagram 240, according to embodiments of the present disclosure

Referring back to FIG. 3, although the following description of the process 190 is described with reference to the DLL 118 of the memory device 100, it should be noted that the process 190 may be performed by other DLLs disposed on other devices. Additionally, although the following process 190 describes a number of operations that may be performed, it should be noted that the process 190 may be performed in a variety of suitable orders and all of the operations may not be performed. At process block 192, the DLL 118 may generate the measure initialization complementary clock signals based on receiving the CLK (e.g., input clock signal) to perform the first step of the measure initialization process (e.g., the 2-step measure initialization process). For example, the deserializer 150 and the clock divider 151 may include divide the CLK to generate the measure initialization complementary clock signals.

As mentioned above with respect to FIG. 2, the measure initialization complementary clock signals may include MI_CLK0 and MI_CLK360 or MI_CLK180 and MI_CLK540. The timing diagram 220 of FIG. 4 illustrates MI_CLK0, MI_CLK180, MI_CLK360, and MI_CLK540 based on a CLK having the first frequency. The timing diagrams 230 and 240 of FIGS. 6 and 7 illustrate MI_CLK0, MI_CLK180, MI_CLK360, and MI_CLK540 based on a CLK having the second frequency. In the depicted embodiment, the timing diagrams 220, 230, and 240 of FIGS. 4, 6, and 7 illustrate MI_CLK0, MI_CLK180, MI_CLK360, and MI_CLK540 along with a respective feedback signal (e.g., MI_CLK FB) having a frequency that is a quarter of a frequency of the respective CLKs when the DLL 118 is performing the measure initialization process. Moreover, the timing diagrams 226 and 250 of FIGS. 5 and 8 illustrate CLK0, CLK90, CLK180, and CLK270 along with a respective feedback signal (e.g., CLK FB) having a frequency that is half of a frequency of the respective CLKs when the DLL 118 is performing the normal operations. It should be appreciated that in alternative or additional embodiments, the timing diagrams 220, 226, 230, 240, and 250 of FIGS. 4-6 may have CLK0, CLK180, CLK90, and CLK270 having a frequency that is a quarter of a frequency of the respective CLKs, among other possibilities.

Referring back to FIG. 3, at process block 194, the DLL 118 may determine a first number of the delay cells 164 based on performing the first step of the measure initialization process to generate the LCLK (e.g., output clock signal) using the measure initialization complementary clock signals. By way of example, the measure initialization circuit 154, including the phase detector 156 and the delay control circuit 158, may determine the first number of the delay cells 164 for selection based on performing the first step using the measure initialization complementary clock signals.

At process block 196, the DLL 118 (e.g., the measure initialization circuit 154, the delay control circuit 158) may determine whether the first number of the delay cells 164 of the variable delay circuit 152 is lower than the threshold. The DLL 118 may proceed to operations of the process block 198 to perform the measure initialization process using a single step. For example, the measure initialization circuit 154 may select the first number of the delay cells 164 of the variable delay circuit 152 when the first number of the delay cells 164 is lower than the threshold. The timing diagram 220 of FIG. 4 may illustrate a first coarse clock adjustment time 222 corresponding to a timing of the measure initialization complementary clock signals based on the CLK having the first frequency.

Referring back to FIG. 3, at process block 198, the DLL 118 may generate the LCLK by combining the measure initialization complementary clock signals as delayed by the first number of the delay cells 164 (e.g., the coarse clock adjustment) based on the CLK having the first frequency. As such, the DLL 118 may generate the LCLK with the desired phase value. The timing diagram 226 of FIG. 5 may illustrate a fine clock adjustment time during normal operations of the DLL 118 after compensating for the first coarse clock adjustment time 222 by the first number of the delay cells 164. The process block 198 of FIG. 3 and the timing diagram 226 of FIG. 5 may correspond to the normal operation of the DLL 118 based on performing the measure initialization process using the first step when the CLK has the first frequency.

Alternatively, process block 196, the DLL 118 may proceed to operations of the process block 200 to perform the second step of the measure initialization process. The DLL 118 may proceed to operations of the process block 200 based on determining that the first number of the delay cells 164 of the variable delay circuit 152 is equal to or higher than the threshold. In some embodiments, the measure initialization circuit 154 may instruct performing the second step of the of the measure initialization process using the measure initialization quadrature clock signals when the first number of the delay cells 164 is equal to or above the threshold.

The timing diagram 230 of FIG. 6 may illustrate a second coarse clock adjustment time 234 (e.g., a coarse delay) of the first step of the measure initialization complementary clock signals based on the CLK having the second frequency lower than the first frequency. For example, the second coarse clock adjustment time 234 of the measure initialization complementary clock of FIG. 6 may be higher than the first coarse clock adjustment time 222 shown in FIG. 4 based on the lower frequency of the CLK in the timing diagram 230 of FIG. 6. Moreover, the coarse delay (or coarse clock adjustment time) may correspond to a number of selected delay cells 164. As such, performing the second step of the measure initialization process using the measure initialization quadrature clock signals may be desirable to reduce the coarse delay and the corresponding number of selected delay cells 164.

Accordingly, the DLL 118 may proceed to operations of the process block 200 when the first number of the delay cells 164 of the variable delay circuit 152 is equal to or higher than the threshold to reduce a number of the selected delay cells 164 for generating the LCLK. In some cases, the DLL 118 may provide a technical advantage by reducing a noise, a jitter, or a skew of the LCLK based on reducing the number of the selected delay cells 164. Additionally or alternatively, the DLL 118 may provide a technical advantage by having a reduced power consumption based on reducing the number of the selected delay cells 164.

Referring back to FIG. 3, at process block 200, the DLL 118 may generate the measure initialization quadrature clock signals based on the CLK. For example, the deserializer 150 and the clock divider 151 may include circuitry (e.g., buffers, inverters, among other possibilities) to divide the CLK to generate the measure initialization quadrature clock signals. As mentioned above, the timing diagram 240 of FIG. 7 illustrates MI_CLK0, MI_CLK180, MI_CLK360, and MI_CLK540 based on a CLK having the second frequency.

At process block 202, the DLL 118 may determine a second number of the delay cells 164 based on performing the second step of the measure initialization process to generate the LCLK using the measure initialization quadrature clock signals. By way of example, the measure initialization circuit 154, including the phase detector 156 and the delay control circuit 158, may determine the second number of the delay cells 164 for selection based on performing the second step using the measure initialization quadrature clock signals. In some cases, the second number of delay cells 164 may be less than the first number of delay cells 164. The DLL 118 may provide a technical advantage by improving a signal quality of the LCLK by reducing the number of the selected delay cells 164.

The timing diagram 240 of FIG. 7 may illustrate a third coarse clock adjustment time 244 corresponding to a timing of the measure initialization quadrature clock signals based on the CLK having the second frequency. The third coarse clock adjustment time 244 may be smaller than the second coarse clock adjustment time 234 (shown in FIG. 6) of the first step of the measure initialization process when receiving the CLK with the second frequency. As such, the second number of the delay cells 164 for providing the third coarse clock adjustment time 244 may be less than that of the second coarse clock adjustment time 234.

At process block 204, the DLL 118 may generate the LCLK by combining the measure initialization quadrature clock signals as delayed by the second number of the delay cells 164. For example, the measure initialization circuit 154 may select the second number of the delay cells 164 of the variable delay circuit 152. Moreover, the deserializer 162 may generate the LCLK based on (e.g., by combining) the measure initialization quadrature clock signals, as delayed or adjusted by the second number of selected delay cells 164, to generate the LCLK with the desired phase value. The timing diagram 250 of FIG. 8 may illustrate a fine clock adjustment time during normal operations of the DLL 118 after compensating for the third coarse clock adjustment time 244 by the second number of the delay cells 164. The process block 204 of FIG. 3 and the timing diagram 250 of FIG. 8 may correspond to the normal operation of the DLL 118 based on performing the measure initialization process using the second step when the CLK has the second frequency.

The specific embodiments described above have been shown by way of example, and it should be understood that these embodiments may be susceptible to various modifications and alternative forms. It should be further understood that the claims are not intended to be limited to the particular forms disclosed, but rather to cover all modifications, equivalents, and alternatives falling within the spirit and scope of this disclosure.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ,” it is intended that such elements are to be interpreted under 35 U.S.C. 112(f). However, for any claims containing elements designated in any other manner, it is intended that such elements are not to be interpreted under 35 U.S.C. 112(f).

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

1. A delay locked loop comprising:
a deserializer configured to generate complementary clock signals and quadrature clock signals based on an input clock signal;
a feedback delay circuit configured to couple to the deserializer, wherein the feedback delay circuit is configured to generate a feedback signal based on the complementary clock signals or the quadrature clock signals;
a measure initialization circuit coupled to the deserializer and the feedback delay circuit, wherein the measure initialization circuit is configured to:
receive the complementary clock signals or the quadrature clock signals and the feedback signal;
determine a phase difference between the complementary clock signals or the quadrature clock signals and the feedback signal; and
determine a clock adjustment based on the phase difference;
a variable delay circuit coupled to the deserializer, the feedback delay circuit, the measure initialization circuit, wherein the variable delay circuit is configured to delay the complementary clock signals and the quadrature clock signals based on the clock adjustment; and
a serializer coupled to the variable delay circuit, wherein the serializer is configured to combine the complementary clock signals and quadrature clock signals, as delayed by the variable delay circuit, to generate an output clock signal.

2. The delay locked loop of claim 1, wherein the deserializer is configured to initially generate the complementary clock signals to adjust the input clock signal based on a desired phase value of the output clock signal.

3. The delay locked loop of claim 2, wherein the serializer is configured to generate the output clock signal by combining the complementary clock signals, as delayed by the variable delay circuit, based on the clock adjustment corresponding to a delay value less than a threshold.

4. The delay locked loop of claim 2, wherein the deserializer is configured to generate the quadrature clock signals based on the clock adjustment corresponding to a delay value equal to or higher than a threshold.

5. The delay locked loop of claim 4, wherein the serializer is configured to generate the output clock signal by combining the quadrature clock signals, as delayed by the variable delay circuit, based on the clock adjustment corresponding to the delay value.

6. The delay locked loop of claim 1, wherein the variable delay circuit comprises a plurality of delay cells, wherein the variable delay circuit is configured to select a number of the plurality of delay cells based on the clock adjustment to delay the complementary clock signals or the quadrature clock signals.

7. The delay locked loop of claim 1, wherein the feedback delay circuit is configured to delay the complementary clock signals and the quadrature clock signals based on a desired phase value of the output clock signal to generate the feedback signal.

8. The delay locked loop of claim 1, wherein the feedback delay circuit is configured to couple to the deserializer via the variable delay circuit.

9. A memory device comprising:
an interface comprising a data driver;
a delay locked loop coupled to the data driver, wherein the delay locked loop is configured to:
generate complementary clock signals based on receiving an input clock signal;
determine a first number of delay cells of a plurality of delay cells by performing a first step of a measure initialization process based on the complementary clock signals to generate an output clock signal with a desired phase;
determine whether the first number of the delay cells is lower than a threshold;
generate the output clock signal by combining the complementary clock signals as delayed by the first number of the delay cells in response to the first number of the delay cells being lower than the threshold;
generate quadrature clock signals based on the input clock signal in response to the first number of the delay cells being equal to or higher than the threshold;
determine a second number of delay cells of the plurality of delay cells by performing a second step of the measure initialization process based on the quadrature clock signals to generate the output clock signal with the desired phase;
generate the output clock signal by combining the quadrature clock signals as delayed by the second number of the delay cells; and
output the output clock signal to the data driver.

10. The memory device of claim 9, wherein the data driver is configured to clock-out read data to an external circuit based on the output clock signal.

11. The memory device of claim 9, wherein the delay locked loop comprises a measure initialization circuit, wherein the measure initialization circuit is configured to determine the first number of delay cells based on the complementary clock signals, and determine whether the first number of the delay cells is lower than a threshold.

12. The memory device of claim 9, wherein the delay locked loop comprises a deserializer configured to generate the complementary clock signals and the quadrature clock signals.

13. The memory device of claim 9, wherein the delay locked loop comprises a serializer configured to generate the output clock signal by combining the complementary clock signals or the quadrature clock signals.

14. The memory device of claim 9, wherein the input clock signal is based on an external clock signal being received from the interface.

15. A delay locked loop comprising:
a deserializer configured to generate complementary clock signals or quadrature clock signals based on an input clock signal;
a plurality of delay cells coupled to the deserializer, wherein selected delay cells of the plurality of delay cells are configured to delay the complementary clock signals and the quadrature clock signals;
a measure initialization circuit coupled to the deserializer and the plurality of delay cells, wherein the measure initialization circuit is configured to:
determine a first number of delay cells to generate an output clock signal with a desired phase value based on the deserializer generating the complementary clock signals;
select the first number of delay cells of the plurality of delay cells based on the deserializer generating the complementary clock signals and the first number of delay cells being less than threshold;
instruct the deserializer to generate the quadrature clock signals in lieu of the complementary clock signals based on the first number of delay cells being equal to or higher than threshold;
determine a second number of delay cells to generate the output clock signal with the desired phase value based on the deserializer generating the quadrature clock signals; and
select the second number of delay cells of the plurality of delay cells based on the deserializer generating the quadrature clock signals; and
a serializer coupled to the plurality of delay cells, wherein the serializer is configured to generate the output clock signal with the desired phase value based on the complementary clock signals as delayed by the first number of delay cells and the quadrature clock signals as delayed by the second number of delay cells.

16. The delay locked loop of claim 15, wherein the deserializer is configured to initially generate the complementary clock signals before receiving the instruction of the measure initialization circuit.

17. The delay locked loop of claim 15, wherein each delay cell delays an input signal by a unit delay value.

18. The delay locked loop of claim 15, wherein each delay cell comprises an inverter or a buffer.

19. The delay locked loop of claim 15, wherein the serializer is configured to generate the output clock signal with the desired phase value by combining the complementary clock signals as delayed by the first number of delay cells and the quadrature clock signals as delayed by the second number of delay cells.

20. The delay locked loop of claim 15, wherein the complementary clock signals and the quadrature clock signals provide a first clock adjustment and the first number of delay cells and the second number of delay cells correspond to a second clock adjustment smaller than the first clock adjustment.
